(19) United States
(12) Patent Application Publication
(10) Pub. No.: US 2014/0198264 A1
(43) Pub. Date: Jul. 17, 2014

(54) METAL MESH CONDUCTIVE LAYER AND TOUCH PANEL HAVING THE SAME

(71) Applicant: NANCHANG O-FILM TECH. CO., LTD, Nanchang, Jiangxi (CN)

(72) Inventors: Yulong Gao, Nanchang (CN); Zheng Cui, Suzhou (CN); Sheng Zhang, Nanchang (CN)

(73) Assignee: NANCHANG O-FILM TECH. CO., LTD, Nanchang, Jiangxi (CN)

(21) Appl. No.: 14/000,192

(22) PCT Filed: Dec. 20, 2012
(86) PCT No.: PCT/CN2012/087077

§ 371 Date: Mar. 17, 2014

(30) Foreign Application Priority Data
May 9, 2012 (CN) 201210141854.2

(51) Int. Cl. H05K 1/11; G06F 3/041

(52) U.S. Cl. CPC H05K 1/11; G06F 3/041
USPC 349/12; 174/255

(57) ABSTRACT

The present invention relates to to a metal mesh conductive layer and touch panel having the conductive layer. A surface of the conductive layer includes a transparent electrode region and an electrode lead region, the transparent electrode region having a mesh made of metal; the electrode lead region having a mesh made of conductive material containing metal. The mesh is made of conductive material containing metal filled in a trench. The transparent electrode region of present invention uses mesh to more uniformly fill the conductive material into the trench, as well as a better bonding to the outside conductive material. The transparent electrode region made of irregular mesh can prevent the generation of Moire.

### FIELD OF THE INVENTION

The present invention relates to conductive layers, and more particularly relates to a metal mesh conductive layer and a touch panel having the conductive layer.

### BACKGROUND OF THE INVENTION

Touch screen is a sensing device used to receive touch input signals. The touch screen gives a new manner for information exchange and thus it is an attractive whole new information exchange device. The development of the touch screen technology has aroused widespread concern at domestic and foreign information media sector, and it has become a sunrise high-tech industries in the photovoltaic field.

The ITO layer is a crucial component for the touch screen module. Although the manufacturing technology of the touch screen has been rapidly developed, taking the projected capacitive screen as an example, the basic manufacturing process of the ITO layer does not change in recent years. The process inevitably includes the ITO coating, the ITO patterning, and the transparent electrode silver wire production. The conventional manufacturing process is complex and lengthy, so that the yield control has become an unavoidable problem in the current touch screen manufacturing stage. In addition, the conventional manufacturing process inevitably needs etching, during which lots of ITO and conductive materials are wasted. Therefore, how to achieve a simple and green process of the ITO layer has become a key technical problem to be solved.

The rapid development of printed electronic technology provides a feasible solution for the above problem. PolyIC Inc. has demonstrated a full printing conductive metal film PolyIC® (http://www.polyic.com/poly-tc.php). Based on the printing technology, the film can one-time produce transparent conductive region having periodic metal mesh and silver wire of the transparent electrode. Therefore, the three processes of the ITO layer can be simplified to a single printing, etching process is omitted and the material waste is controlled.

However, the PolyIC® is produced based on conventional printing technology, thus the smallest linewidth can only reach 10 μm. On the premise that the permeability is greater than 85%, the grid period must be greater than 300 μm. Thus this mesh can be clearly perceived visually.

An embedded metal mesh based on nanoimprint technology can achieve a silver wire processing with a width less than 3 μm. It has been tested that when the silver wire of the transparent electrode region has a width less than 3 μm, the human eye can not perceive. However, the width of the silver lead of the transparent electrode is usually greater than 20 μm. If the trench depths are the same, the different width means different depth-to-width ratio of the trench depth. Larger changes of depth-to-width ratio will cause great difficulty for the silver filling process in the trench.

### SUMMARY OF THE INVENTION

In one aspect of the present invention, a metal mesh conductive layer and touch panel having the conductive layer are provided, which use metal mesh with different density to create a transparent electrode region and an electrode lead region, simultaneously; the metal mesh in the electrode lead region is invisible for the user.

The technical problem solved by the invention is achieved the following technical solutions:

A metal mesh conductive layer is provided. A surface of the conductive layer includes a transparent electrode region and an electrode lead region, the transparent electrode region has a mesh made of metal; the electrode lead region has a mesh made of conductive material containing metal. The mesh is made of conductive material containing metal filled in a trench.

Preferably, the mesh of the electrode lead region is a regular polygon mesh.

Preferably, the mesh of the transparent electrode region is a random irregular mesh, the mesh of the transparent electrode region is composed of gridlines thereof, the gridlines of the transparent electrode region are evenly distributed in each angular direction.

Preferably, the irregular mesh is composed of irregular polygons; the gridlines of the mesh are straight segments, and angles θ formed by gridlines and the right horizontal direction X are evenly distributed, when angles θ for each irregular mesh is counted, using 5° as an interval, the probability pᵢ that segments fall within each interval are counted, whereby p₁, p₂, . . . and p₃₆ are obtained in 36 angle intervals within 0-180°; and pᵢ satisfy the standard deviation is less than 20% of the arithmetic mean. Preferably, a relative transmittance of the mesh of the electrode lead region is less than 80%.

Preferably, the trench has a substantially rectangular cross-section, a ratio of a depth to a width of the trench exceeds 0.8, and the width of the trench is less than 10 μm.

Preferably, the conductive layer has an alignment mark, the alignment mark has a mesh made of metal and a transmittance less than 80%.

Preferably, the conductive layer is composed of: at least a substrate material and a conductive material bottom-up; or at least a substrate material, a polymer material, and a conductive material bottom-up; or at least a conductive material, a substrate material, and a conductive material bottom-up; or at least a conductive material, a polymer material, a substrate material, a polymer material, and a conductive material bottom-up; wherein the polymer material is a UV-curable material, a thermoplastic material, or a thermosetting material.

A touch panel includes at least one metal mesh conductive layer described above.

The invention has some advantages such as:
(1) The electrode lead region of the present invention is provided using mesh design, when it is to be bonded to the flexible printed board, the polymer portion of the mesh can enhance the adhesive force between the pin and the conductive adhesive of the flexible circuit board, thus improving the bonding firmness. The electrode lead region is provided using mesh design, which is the first innovation different from the prior art.
(2) The electrode lead region of the present invention is provided using trench design with a trench width less than 10 μm, which unifies the trench width of the transparent electrode region and the trench width of electrode lead region, thus facilitating the selection of the trench depth, meanwhile facilitating the subsequent unification of process parameters of filling the conductive material, and improving the filling uniformity of the conductive material. The electrode lead region is provided using trench design, which the second innovation different from the prior art.
(3) The transparent electrode region of the present invention is composed of irregular mesh, when the transparent electrode region composed of irregular mesh is attached to the surface of a LCD, the generation of moiré is prevented. The electrode lead region is composed of regular or irregular mesh. Although moiré will be generated by the regular mesh of the electrode lead region, when it is attached to the surface of the LCD, the electrode lead region is located in an area invisible to the user. Regular mesh and irregular mesh are both applied to the conductive layer, which the third innovation different from the prior art.

### BRIEF DESCRIPTION OF THE DRAWINGS

FIG. 1 is a schematic, cross-sectional view of an embedded metal mesh conductive layer according to the present invention;

FIG. 2 is a schematic, plan view of the embedded metal mesh conductive layer according to the present invention;

FIG. 3 is a partial enlarged view in correspondence with K shown in FIG. 2;

FIG. 4 is a schematic view of the random mesh of the embedded metal mesh conductive layer according to the present invention;

FIG. 5 is a schematic view showing an angle θ formed by each segment of the random mesh of the embedded metal mesh conductive layer and X axis.

FIG. 6 is a diagram showing the distribution of the probability P of the angle

A formed by each segment of the random mesh of the embedded metal mesh conductive layer and X axis.

FIG. 7 is a schematic view showing an alignment mark of the present invention;

FIG. 8 is a partial enlarged view in correspondence with L shown in FIG. 7.

### DETAILED DESCRIPTION

The invention will be described in further detail below in conjunction with the drawing.

### Embodiment One

A conductive layer is provided having an electrode lead region made of regular mesh.

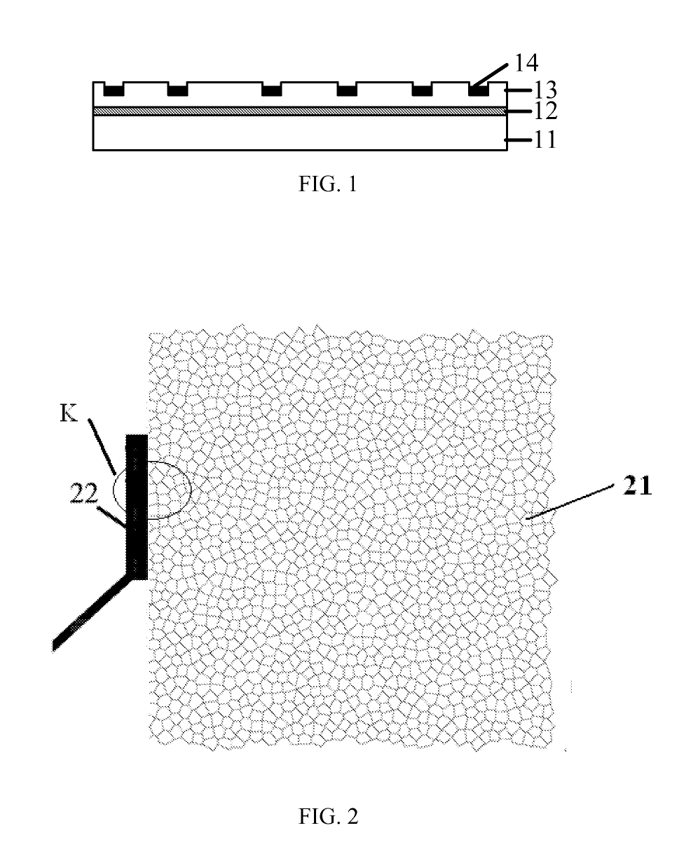

FIG. 1 is a schematic, cross-sectional view of an embedded metal mesh conductive layer according to an embodiment. The conductive layer includes, bottom-up, a substrate PET 11 with a thickness of 188 μm; a thickening layer 12; and a UV acrylic adhesive 13 having trenches, which has a depth of 3 μm and a width of 2.2 μm. The trench is filled with silver 14 having a thickness of about 2 μm, which is smaller than the depth of the trench.

FIG. 2 is a schematic, plan view of the embedded metal mesh conductive layer according to the present embodiment. The conductive layer includes a transparent electrode region 21 and an electrode lead region 22. The transparent electrode region 21 is composed of a random irregular mesh with a linewidth of 2.2 μm. An average diameter R of the mesh is preferably 120 μm, and the relative transmittance is 96%. Since the selected PET of the present embodiment has an average transmittance of 91.4% in the visible band, the total transmittance of the transparent electrode is 87.72%. The electrode lead region 22 is composed of orthogonal grid lines with a linewidth of 2.2 μm, a cycle of 8 μm having a relative transmittance of 53.5%.

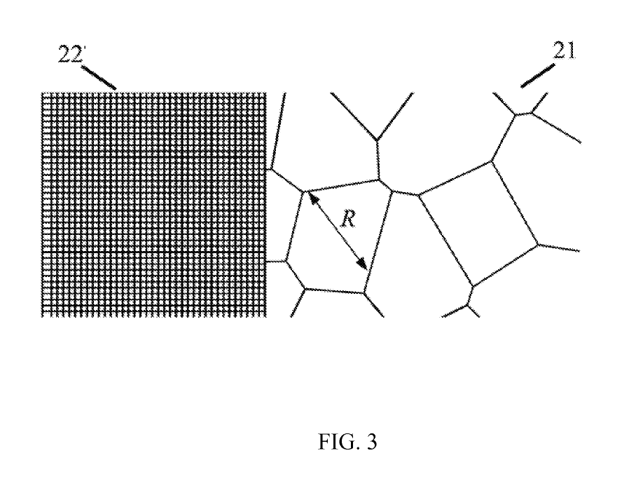

FIG. 2 is a schematic, plan view of the embedded metal mesh conductive layer according to the present embodiment, and 22′ in FIG. 3 is a partial enlarged view of the electrode lead region 22. As it can be seen from the enlarged view that the electrode lead region 22′ is composed of regular meshes. The black strip in the electrode lead region 22′ is the metal silver 14 of the conductive region; the blank area is an insulating region; the blank area in the electrode lead region 22′ is UV acrylic adhesive 13, such that the electrode lead region 22′ and the outside conductive material can be better bonded, the greater the bonding, the better the adhesion.

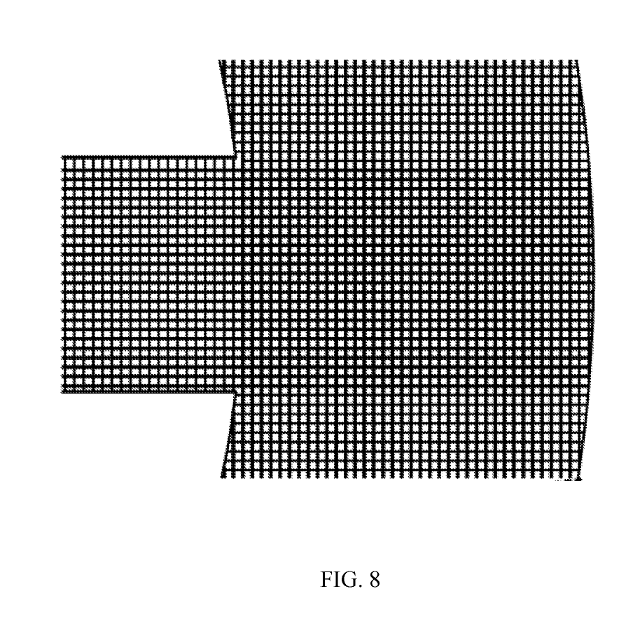

An alignment mark 31 of the embedded metal mesh conductive layer of the present embodiment is shown in FIG. 7. The alignment mark 31 is also composed of orthogonal grid lines with a linewidth of 2.2 μm, a cycle of 8 μm having a relative transmittance of 53.5%. FIG. 8 is a partial enlarged view in correspondence with L shown in FIG. 7. As can be seen from FIG. 8 that the alignment mark 31 is composed by meshes.

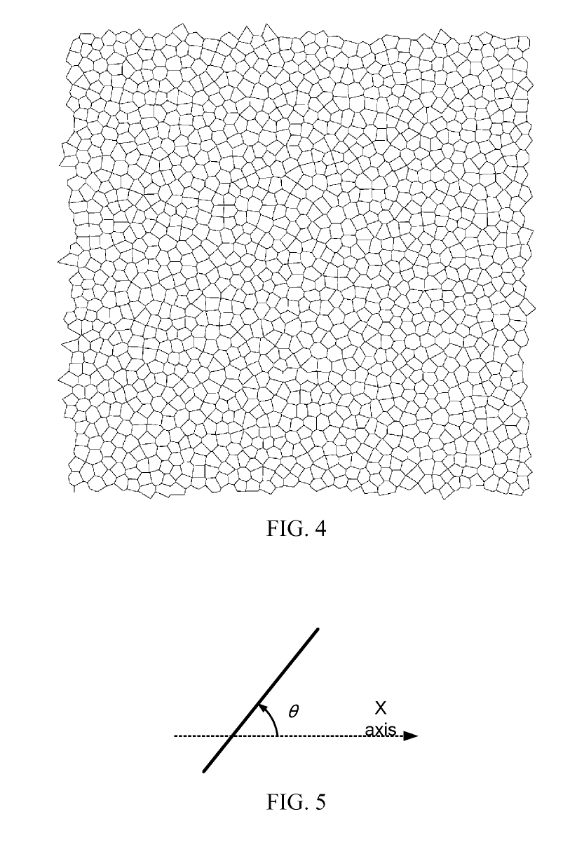

The processing method of the embodiment is prior art. In the illustrated embodiment, the type of the random mesh is an isotropic random irregular polygonal mesh. The angle distribution will be analyzed taking random mesh of 5 mm*5 mm shown in FIG. 4 as an example.

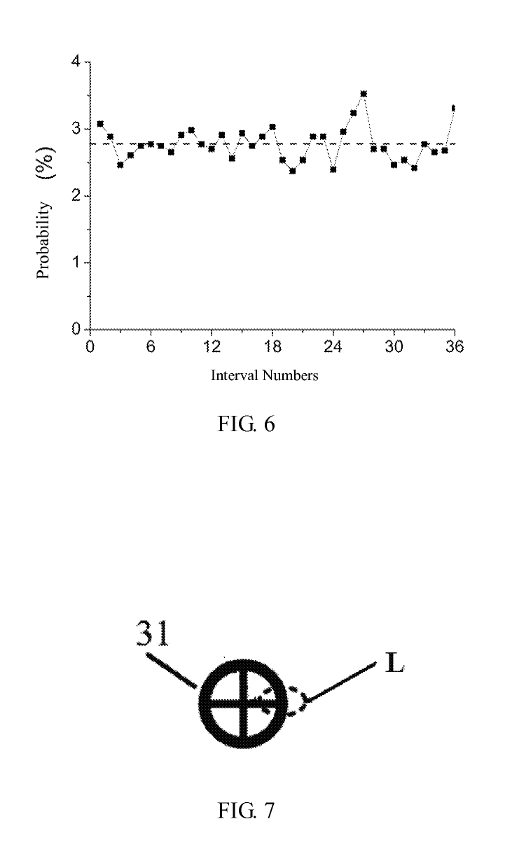

The random mesh shown in FIG. 4 includes 4257 segments. Referring to FIG. 5, an one-dimensional array θ(1)-θ(4257) can be obtained by counting each angle θ formed by the segments between the X axis; 0-180° is then divided into 36 angle intervals using 5° as an interval; the probability p that segments fall within each interval is counted, and an one-dimensional array p(1)-p(36) is obtained, as shown in FIG. 6. According to the standard deviation formula:

$$s = \sqrt{\frac{{( {p}_{1} - \overline{p} )}^{2} + {( {p}_{2} - \overline{p} )}^{2} + … {( {p}_{n} - \overline{p} )}^{2}}{n}}$$

where n is 36, a standard deviation s of 0.26% and an average probability p̅ of 2.78% are obtained. Since s/ p̅=9.31%, the grid lines of the random mesh is evenly distributed in the angular, thus it can effectively prevent the generation of moire.

In the illustrated embodiment, the random mesh of the irregularly shaped transparent electrode region may have an irregular honeycomb structure; in practice, the irregular shaped and non-periodic random mesh can be cyclically spliced by local aperiodic mesh unit with a splicing cycle greater than 1 mm.

A touch panel according to the present invention has the metal mesh conductive layer shown in FIG. 1 and FIG. 2. The composition of the touch panel is GFF mode, i.e., the touch panel has two metal mesh conductive layers with the features above, and an OCA is located between the two layers.

The substrate of the present embodiment may be glass, or UV acrylic adhesive having trenches, it can also be replaced by organic materials having the same features as the UV adhesive, such as, a UV curable material, a thermoplastic material or a thermosetting material, for example, PMMA, PC, PDMS, etc. The metal mesh conductive layer may be double-sided, the composition of the touch panel may not be limited and can be GG, on-cell, or GF2, etc. The conductive layer of the present embodiment may be composed of: at least a substrate material and a conductive material bottom-up; or at least a substrate material, a polymer material, and a conductive material bottom-up; or at least a conductive material, a substrate material, and a conductive material bottom-up; or at least a conductive material, a polymer material, a substrate material, a polymer material, and a conductive material bottom-up. The polymer material is a UV-curable material, a thermoplastic material, or a thermosetting material.

Although the invention has been described in language specific to structural features and/or methodological acts, it is to be understood that the invention defined in the appended claims is not necessarily limited to the specific features or acts described. Rather, the specific features and acts are disclosed as sample forms of implementing the claimed invention.

1. A metal mesh conductive layer, a surface of the conductive layer comprising a transparent electrode region and an electrode lead region, the transparent electrode region having a mesh made of metal; the electrode lead region having a mesh made of conductive material containing metal; the mesh is made of conductive material containing metal filled in a trench.

2. The metal mesh conductive layer according to claim 1, wherein the mesh of the electrode lead region is a regular polygon mesh.

3. The metal mesh conductive layer according to claim 1, wherein the mesh of the transparent electrode region is a random irregular mesh, the mesh of the transparent electrode region is composed of gridlines thereof, the gridlines of the transparent electrode region are evenly distributed in each angular direction.

4. The metal mesh conductive layer according to claim 3, wherein the irregular mesh is composed of irregular polygons; the gridlines of the mesh are straight segments, and angles θ formed by gridlines and the right horizontal direction X are evenly distributed, when angles θ for each irregular mesh is counted, using 5° as an interval, the probability pi that segments fall within each interval are counted, whereby p1, p2, . . . and p36 are obtained in 36 angle intervals within 0-180°; and pi satisfy the standard deviation is less than 20% of the arithmetic mean.

5. The metal mesh conductive layer according to claim 1, wherein a relative transmittance of the mesh of the electrode lead region is less than 80%.

6. The metal mesh conductive layer according to claim 1, wherein the trench has a substantially rectangular cross-section, a ratio of a depth to a width of the trench exceeds 0.8, and the width of the trench is less than 10 μm.

7. The metal mesh conductive layer according to claim 1, wherein the conductive layer has an alignment mark, the alignment mark has a mesh made of metal and a transmittance less than 80%.

8. The metal mesh conductive layer according to claim 1, wherein the conductive layer is composed of: at least a substrate material and a conductive material bottom-up; or at least a substrate material, a polymer material, and a conductive material bottom-up; or at least a conductive material, a substrate material, and a conductive material bottom-up; or at least a conductive material, a polymer material, a substrate material, a polymer material, and a conductive material bottom-up; wherein the polymer material is a UV-curable material, a thermoplastic material, or a thermosetting material.

9. A touch panel, comprising at least one metal mesh conductive layer according to claim 1.

10. The metal mesh conductive layer according to claim 2, wherein the mesh of the transparent electrode region is a random irregular mesh, the mesh of the transparent electrode region is composed of gridlines thereof, the gridlines of the transparent electrode region are evenly distributed in each angular direction.

11. The metal mesh conductive layer according to claim 2, wherein a relative transmittance of the mesh of the electrode lead region is less than 80%.

12. The metal mesh conductive layer according to claim 2, wherein the trench has a substantially rectangular cross-section, a ratio of a depth to a width of the trench exceeds 0.8, and the width of the trench is less than 10 μm.

13. The metal mesh conductive layer according to claim 2, wherein the conductive layer has an alignment mark, the alignment mark has a mesh made of metal and a transmittance less than 80%.

14. The metal mesh conductive layer according to claim 2, wherein the conductive layer is composed of: at least a substrate material and a conductive material bottom-up; or at least a substrate material, a polymer material, and a conductive material bottom-up; or at least a conductive material, a substrate material, and a conductive material bottom-up; or at least a conductive material, a polymer material, a substrate material, a polymer material, and a conductive material bottom-up; wherein the polymer material is a UV-curable material, a thermoplastic material, or a thermosetting material.
